(19) United States
(12) Patent Application Publication
(10) Pub. No.: US 2018/0287432 A1
(43) Pub. Date: Oct. 4, 2018

(54) ADAPTIVE ADC CONTROL FOR LIVING OBJECT PROTECTION

(71) Applicant: QUALCOMM Incorporated, San Diego, CA (US)

(72) Inventor: Qi WANG, Ottobrunn (DE)

(21) Appl. No.: 15/838,678

(22) Filed: Dec. 12, 2017

Related U.S. Application Data
(60) Provisional application No. 62/478,268, filed on Mar. 29, 2017.

(51) Int. Cl. H02J 50/60; G01S 13/04; G01S 7/40; H03M 1/12; B60L 11/18

(52) U.S. Cl. CPC H02J 50/60; G01S 13/04; B60L 11/182; H03M 1/124; G01S 7/4021

(57) ABSTRACT

Certain aspects of the present disclosure generally relate to methods and apparatus for adaptively controlling an analog-to-digital converter (ADC), such as an ADC in a living or moving object detection system integrated into a base pad of a wireless power transmitter. One example method for operating an object detection system generally includes sampling a radar input signal with an ADC of the object detection system, determining an actual radar signal level based on the sampled radar input signal, comparing the actual radar signal level with a target radar signal level, and adjusting one or more parameters of the ADC based on the comparison.

### CROSS-REFERENCE TO RELATED APPLICATIONS

The present application claims the benefit of U.S. Provisional Patent Application Ser. No. 62/478,268, filed Mar. 29, 2017 and entitled “Adaptive ADC Control for Living Object Protection,” which is herein incorporated by reference in its entirety.

### TECHNICAL FIELD

The present disclosure generally relates to wireless power transfer and, more specifically, to adaptively controlling an analog-to-digital converter (ADC) in an object detection system of a wireless power transfer application.

### BACKGROUND

Electric vehicles (EV) are designed to derive locomotion power from electricity received from an energy storage device, such as a battery. For example, hybrid electric vehicles include on-board chargers that use power from vehicle braking and traditional motors to charge the vehicles. Vehicles that are solely electric generally receive power for charging the batteries of the vehicle from other sources. EVs are often proposed to be charged through some type of wired alternating current (AC) source, such as household or commercial AC supply sources. The wired charging connections use cables or other similar connectors that are physically connected to a power supply. Cables and similar connectors may be inconvenient or cumbersome and have other drawbacks. Wireless charging systems that are capable of transferring power in free space (e.g., via a wireless field) to be used to charge electric vehicles may overcome some of the deficiencies of wired charging solutions. As such, design of wireless charging systems and methods that efficiently transfer power for charging EVs are important.

Inductive power transfer (IPT) systems provide one example of wireless transfer of energy. In IPT systems, a primary power device (or “transmitter”) transmits power wirelessly to a secondary power device (or “receiver”). Each of the transmitter and receiver includes an inductive coupler, typically a single or multi-coil arrangement of windings comprising electric current conveying materials. An alternating current passing through a primary coupler produces an alternating magnetic field. When a secondary coupler is placed in proximity to the primary coupler, the alternating magnetic field induces an electromotive force (EMF) in the secondary coupler according to Faraday's law, thereby wirelessly transferring power to the receiver.

Inductive power transfer to electrically chargeable vehicles at power levels of several kilowatts in both private and public parking zones may implicate the use of special protective measures for the safety of people, animals, and equipment in proximity. Such measures may include detection of moving objects in the critical space of the IPT system. This may be particularly true for systems where the critical space is open and accessible. Such measures may also include detection of living objects, (e.g., humans, extremities of humans, or animals) to protect these objects from exposure to such strong electromagnetic fields.

The critical space of an IPT system may be defined as the space where electromagnetic field levels exceed certain critical levels. These levels may be based on regulatory limits for human exposure, magnetic flux density limits determined by eddy current heating effects in foreign metallic objects, or other limits such as those specified by a standard applicable to a particular product or to a particular use case. As such, systems, methods, and apparatus for living object protection in wireless power transfer applications are desirable.

### SUMMARY

Certain aspects of the present disclosure generally relate to adaptively controlling an analog-to-digital converter (ADC) in an object detection system, such as in a wireless power transfer application. The objection detection system may include, for example, a foreign object detection (FOD) system or a living object protection (LOP) system.

Certain aspects of the present disclosure provide a method for operating an object detection system. The method generally includes sampling a radar input signal with an ADC of the object detection system, determining an actual radar signal level based on the sampled radar input signal, comparing the actual radar signal level with a target radar signal level, and adjusting one or more parameters of the ADC based on the comparison.

Certain aspects of the present disclosure provide an apparatus for objection detection in a wireless power transfer application. The apparatus includes an ADC configured to sample a radar input signal and a processor having an input coupled to an output of the ADC. The processor is generally configured to determine an actual radar signal level based on the sampled radar input signal, to compare the actual radar signal level with a target radar signal level, and to output at least one control signal configured to adjust one or more parameters of the ADC based on the comparison.

Certain aspects of the present disclosure provide an apparatus for objection detection in a wireless power transfer application. The apparatus generally includes means for sampling a radar input signal, means for determining an actual radar signal level based on the sampled radar input signal, means for comparing the actual radar signal level with a target radar signal level, and means for adjusting one or more parameters of the means for sampling based on the comparison between the actual radar signal level and the target radar signal level.

The following detailed description and accompanying drawings provide a better understanding of the nature and advantages of the present disclosure.

### BRIEF DESCRIPTION OF THE DRAWINGS

With respect to the discussion to follow and in particular to the drawings, it is stressed that the particulars shown represent examples for purposes of illustrative discussion, and are presented in the cause of providing a description of principles and conceptual aspects of the present disclosure. In this regard, no attempt is made to show implementation details beyond what is needed for a fundamental understanding of the present disclosure. The discussion to follow, in conjunction with the drawings, makes apparent to those of skill in the art how aspects in accordance with the present disclosure may be practiced. In the accompanying drawings:

FIG. 1 is a functional block diagram of an example wireless power transfer system, in accordance with certain aspects of the present disclosure.

FIG. 2 is a more-detailed block diagram of an example wireless power transfer system, in accordance with certain aspects of the present disclosure.

FIG. 3 is a schematic diagram of a portion of example transmit or receive circuitry of FIG. 2 including a power transmitting or receiving element, in accordance with certain aspects of the present disclosure.

FIG. 4 is a functional block diagram of an example wireless power transfer system for charging a battery of a vehicle, in accordance with certain aspects of the present disclosure.

FIG. 5 illustrates an example living or moving object detection system integrated into a base pad of a wireless power transmitter, in accordance with certain aspects of the present disclosure.

FIG. 6 is a block diagram of a radar module front-end and a back-end for adaptive control of an analog-to-digital converter (ADC) in the front-end, in accordance with certain aspects of the present disclosure.

FIG. 7 is a flow diagram of example operations for an objection detection system with adaptive ADC control, in accordance with certain aspects of the present disclosure.

### DETAILED DESCRIPTION

Drawing elements that are common among the following figures may be identified using the same reference numerals.

Wireless power transfer may refer to transferring any form of energy associated with electric fields, magnetic fields, electromagnetic fields, or otherwise from a transmitter to a receiver without the use of physical electrical conductors (e.g., power may be transferred through free space or air). The power output into a wireless field (e.g., a magnetic field or an electromagnetic field) may be received, captured by, or coupled by a “wireless power receiving element” to achieve power transfer. In certain aspects, the wireless power receiving element may be located in an electric vehicle (EV) and used to charge a battery of the EV, as described in more detail below.

### Example Wireless Power Transfer Systems

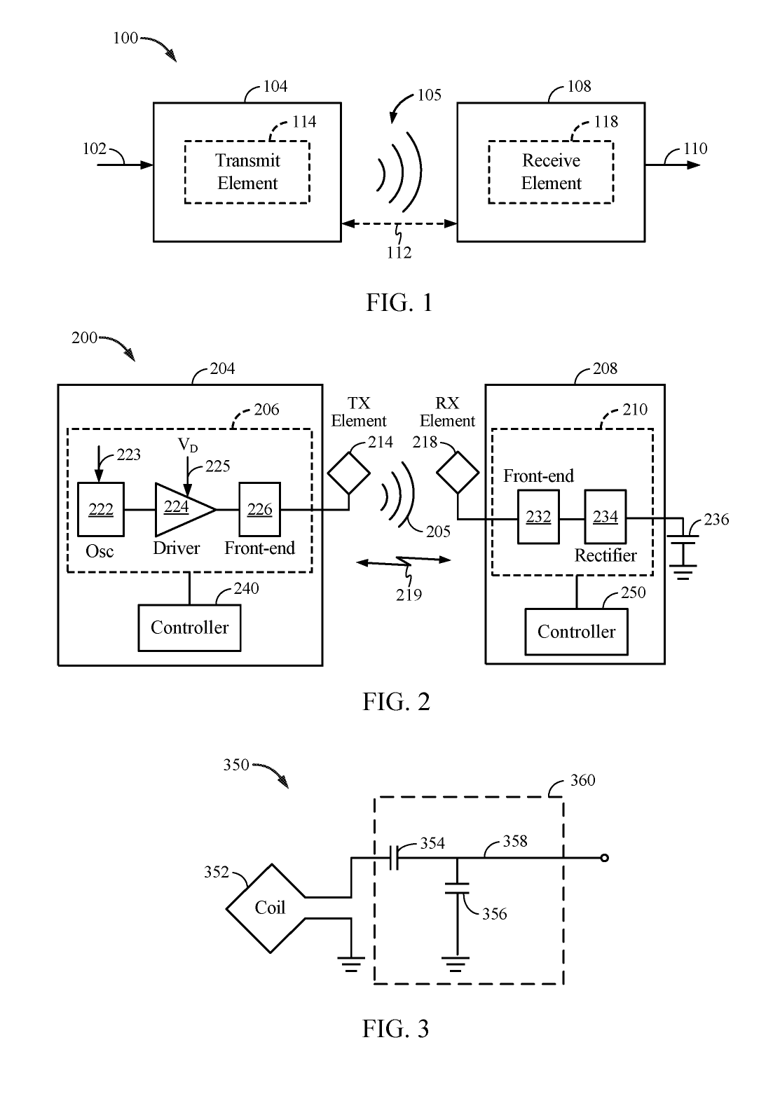

FIG. 1 is a functional block diagram of an example wireless power transfer system 100, in accordance with certain aspects of the present disclosure. Input power 102 may be provided to a transmitter 104 from a power source (not shown in this figure) to generate a wireless (e.g., magnetic or electromagnetic) field 105 for performing energy transfer. A receiver 108 may be subjected to the wireless field 105 and generate output power 110 for storing or consumption by a device (e.g., a battery of an EV) coupled to the output power 110. The transmitter 104 and the receiver 108 may be separated by a distance 112. The transmitter 104 may include a power transmitting element 114 for transmitting/providing energy to the receiver 108. The receiver 108 may include a power receiving element 118 for receiving/capturing energy transmitted from the transmitter 104.

In one illustrative aspect, the transmitter 104 and the receiver 108 may be configured according to a mutual resonant relationship. When the resonant frequency of the receiver 108 and the resonant frequency of the transmitter 104 are substantially the same or very close, transmission losses between the transmitter 104 and the receiver 108 are reduced. As such, wireless power transfer may be provided over larger distances. Resonant inductive coupling techniques may thus allow for increased efficiency and power transfer over various distances and with a variety of inductive power transmitting and receiving element configurations.

In certain aspects, the wireless field 105 may correspond to the “near field” of the transmitter 104. The near field may correspond to a region in which there are strong reactive fields resulting from the currents and charges in the power transmitting element 114 that minimally radiate power away from the power transmitting element 114. The near field may correspond to a region that is within about one wavelength (or a fraction thereof) of the power transmitting element 114. Conversely, the far field may correspond to a region that is greater than about one wavelength of the power transmitting element 114.

In certain aspects, efficient energy transfer may occur by coupling a large portion of the energy in the wireless field 105 to the power receiving element 118, rather than propagating most of the energy in an electromagnetic wave to the far field.

In certain implementations, the transmitter 104 may output a time-varying magnetic (or electromagnetic) field with a frequency corresponding to the resonant frequency of the power transmitting element 114. When the receiver 108 is within the wireless field 105, the time-varying magnetic (or electromagnetic) field may induce a current in the power receiving element 118. As described above, if the power receiving element 118 is configured as a resonant circuit to resonate at (or very close to) the frequency of the power transmitting element 114, energy may be efficiently transferred. An alternating current (AC) signal induced in the power receiving element 118 may be rectified to produce a direct current (DC) signal that may be provided to charge or to power a load (e.g., a battery of an EV).

FIG. 2 is a more-detailed block diagram of an example wireless power transfer system 200, in accordance with certain aspects of the present disclosure. The system 200 may include a transmitter 204 and a receiver 208. The transmitter 204 (also referred to herein as a power transfer unit, or PTU) may include transmit circuitry 206 that may include an oscillator 222, a driver circuit 224, and a front-end circuit 226. The oscillator 222 may be configured to generate an oscillator signal (also known as an oscillating signal) at a desired frequency (e.g., fundamental frequency), which may be adjusted in response to a frequency control signal 223. The oscillator 222 may provide the oscillator signal to the driver circuit 224. The driver circuit 224 may be configured to drive the power transmitting element 214 at, for example, a resonant frequency of the power transmitting element 214, according to the frequency of the oscillator signal. The power transmitting element 214 may be powered by a power supply signal (V_{D}) 225. The driver circuit 224 may be a switching amplifier configured to receive a square wave from the oscillator 222 and output a sine wave as a driving signal output.

The front-end circuit 226 may include a filter circuit configured to filter out harmonics or other unwanted frequencies. The front-end circuit 226 may also include a matching circuit configured to match the impedance of the transmitter 204 to the impedance of the power transmitting element 214 in an effort to reduce power loss. As explained in more detail below, the front-end circuit 226 may include a tuning circuit to create a resonant circuit with the power transmitting element 214. As a result of driving the power transmitting element 214, the power transmitting element 214 may generate a wireless field 205 to wirelessly output power at a level sufficient for charging a battery 236, or otherwise powering a load.

The transmitter 204 may further include a controller 240 operably coupled to the transmit circuitry 206 and configured to control one or more aspects of the transmit circuitry 206, or accomplish other operations relevant to managing the transfer of power. The controller 240 may be a microcontroller or a processor, for example. For certain aspects, the controller 240 may be implemented as an application-specific integrated circuit (ASIC). The controller 240 may be operably connected, directly or indirectly, to each component of the transmit circuitry 206. The controller 240 may be further configured to receive information from each of the components of the transmit circuitry 206 and perform calculations based on the received information. The controller 240 may be configured to generate control signals (e.g., signal 223) for each of the components that may adjust the operation of that component. As such, the controller 240 may be configured to adjust or manage the power transfer based on a result of the operations performed by it. The transmitter 204 may further include a memory (not shown) configured to store data, such as instructions for causing the controller 240 to perform particular functions, such as those related to management of wireless power transfer.

The receiver 208 (also referred to herein as a power receiving unit, or PRU) may include receive circuitry 210 that may include a front-end circuit 232 and a rectifier circuit 234. The front-end circuit 232 may include matching circuitry configured to match the impedance of the receive circuitry 210 to the impedance of the power receiving element 218 in an effort to reduce power loss. As will be explained below, the front-end circuit 232 may further include a tuning circuit to create a resonant circuit with the power receiving element 218. The rectifier circuit 234 may generate a DC power output from an AC power input to charge the battery 236, as shown in FIG. 2, or power a load. The receiver 208 and the transmitter 204 may additionally communicate on a separate communication channel 219 using any suitable radio access technology (e.g., Bluetooth, Zigbee, cellular, etc.). The receiver 208 and the transmitter 204 may alternatively communicate via in-band signaling using characteristics of the wireless field 205.

The receiver 208 may be configured to determine whether an amount of power transmitted by the transmitter 204 and received by the receiver 208 is appropriate for charging the battery 236. In certain aspects, the transmitter 204 may be configured to generate a predominantly non-radiative field with a direct field coupling coefficient (k) for providing energy transfer. Receiver 208 may directly couple to the wireless field 205 and may generate an output power for storing or consumption by a battery 236 (or load) coupled to the output or receive circuitry 210.

The receiver 208 may further include a controller 250 configured similarly to the transmit controller 240 as described above for managing one or more aspects of the receiver 208. The receiver 208 may further include a memory (not shown) configured to store data, such as instructions for causing the controller 250 to perform particular functions, such as those related to management of wireless power transfer.

As discussed above, transmitter 204 and receiver 208 may be separated by a distance and may be configured according to a mutual resonant relationship to minimize transmission losses between the transmitter 204 and the receiver 208.

FIG. 3 is a schematic diagram of a portion of the transmit circuitry 206 or the receive circuitry 210 of FIG. 2, in accordance with certain aspects of the present disclosure. As illustrated in FIG. 3, transmit or receive circuitry 350 may include a power transmitting or receiving element 352 and a tuning circuit 360. The power transmitting or receiving element 352 may also be referred to or be configured as an antenna or a “loop” antenna. The term “antenna” generally refers to a component that may wirelessly output or receive energy for coupling to another antenna. The power transmitting or receiving element 352 may also be referred to herein or be configured as a “magnetic” antenna, or an induction coil, a resonator, or a portion of a resonator. The power transmitting or receiving element 352 may also be referred to as a coil or resonator of a type that is configured to wirelessly output or receive power. As used herein, the power transmitting or receiving element 352 is an example of a “power transfer component” of a type that is configured to wirelessly output and/or receive power. The power transmitting or receiving element 352 may include an air core or a physical core such as a ferrite core (not shown in this figure).

When the power transmitting or receiving element 352 is configured as a resonant circuit or resonator with tuning circuit 360, the resonant frequency of the power transmitting or receiving element 352 may be based on the inductance and capacitance. Inductance may be simply the inductance created by a coil and/or other inductor forming the power transmitting or receiving element 352. Capacitance (e.g., a capacitor) may be provided by the tuning circuit 360 to create a resonant structure at a desired resonant frequency. As a non-limiting example, the tuning circuit 360 may comprise a capacitor 354 and a capacitor 356, which may be added to the transmit and/or receive circuitry 350 to create a resonant circuit.

The tuning circuit 360 may include other components to form a resonant circuit with the power transmitting or receiving element 352. As another non-limiting example, the tuning circuit 360 may include a capacitor (not shown) placed in parallel between the two terminals of the circuitry 350. Still other designs are possible. In some aspects, the tuning circuit in the front-end circuit 226 may have the same design (e.g., 360) as the tuning circuit in front-end circuit 232. In other aspects, the front-end circuit 226 may use a tuning circuit design different from the front-end circuit 232.

For power transmitting elements, the signal 358, with a frequency that substantially corresponds to the resonant frequency of the power transmitting or receiving element 352, may be an input to the power transmitting or receiving element 352. For power receiving elements, the signal 358, with a frequency that substantially corresponds to the resonant frequency of the power transmitting or receiving element 352, may be an output from the power transmitting or receiving element 352. Although aspects disclosed herein may be generally directed to resonant wireless power transfer, persons of ordinary skill in the art will appreciate that aspects disclosed herein may be used in non-resonant implementations for wireless power transfer.

In some aspects, when power is wirelessly received by a device (e.g., an electric vehicle) with a wireless power receiver (e.g., receiver 208) from a wireless power transmitter (e.g., transmitter 204), there may be a method of power control to ensure that the correct amount of power is transferred from the transmitter 204 to the receiver 208. For example, the device with the receiver 208 may be configured to operate or charge at a particular voltage (e.g., 4.2 V). However, generating a fixed strength wireless field 205 by the transmitter 204 may not produce the desired voltage at the receiver 208. For example, the amount of power transferred between the transmitter 204 and the receiver 208 at any given strength of the wireless field 205 may differ based on the distance between (and/or other factors such as materials between, etc.) the transmitter 204 and the receiver 208. Accordingly, the power generated by the receiver 208 for the device may be variable based on one or more factors for the same strength of wireless field 205 from the transmitter 204.

In some aspects, a closed-loop power control scheme may be employed to adjust the strength of the wireless field 205 to ensure that the power (e.g., voltage) at the device being wirelessly powered is the desired power (e.g., desired voltage). For example, in some aspects, the wireless receiver 208 may be configured to actively determine a power level of the power received at the receiver 208, such as, a voltage at the rectifier circuit 234. For example, the controller 250 may be configured to monitor the voltage at the rectifier circuit 234. Depending on whether the voltage at the rectifier circuit 234 is above or below a range of the desired voltage level, the wireless receiver 208 (e.g., as controlled by the controller 250) may transmit feedback information (e.g., as a control signal) (e.g., via communication channel 219 or in-band signaling using the wireless field 205) to the wireless transmitter 204 indicating whether a strength of the wireless field 205 should be increased or decreased. No control signal may be sent if the voltage at the rectifier circuit 234 is within the range of the desired voltage level. The wireless transmitter 204 may receive the control signal and adjust the strength of the wireless field 205 (e.g., by control from the controller 240), accordingly.

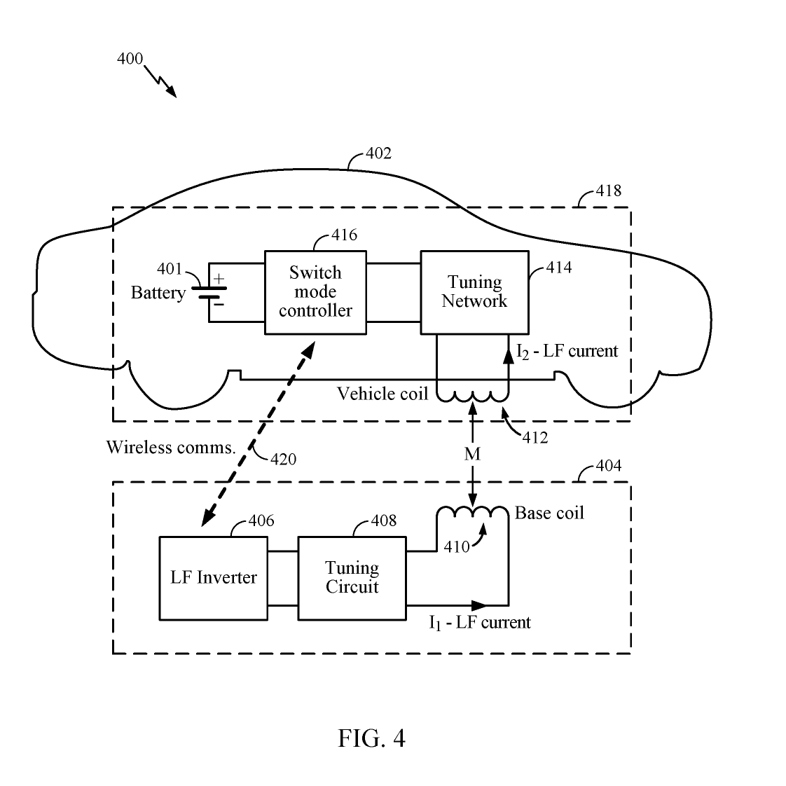

FIG. 4 is a functional block diagram of an example wireless power transfer system 400 for charging a battery 401 of a vehicle 402 with transmit circuitry 404, in accordance with certain aspects of the present disclosure. Transmit circuitry 404 may include an inverter 406 (e.g., a low-frequency (LF) inverter) configured to generate an alternating current (AC) signal from a direct current (DC) signal. The output of the inverter 406 may be coupled to a tuning circuit 408 configured to supply a current (e.g., a LF current) to a wireless charging element, implemented via a coil 410, for example. The coil 410 may be located in a base pad installed, for example, in a motorway. Supplying the current to coil 410 generates a magnetic field (M) that is coupled onto a wireless power receiving element, implemented via a coil 412, of receive circuitry 418. As illustrated, the coil 412 may be located at or near a bottom of the vehicle 402. The coil 412 generates a current 1₂ provided to a tuning network 414. In certain aspects, the tuning network 414 may be coupled to a switch-mode controller 416 configured to generate a regulated DC voltage to charge the battery 401 of the vehicle 402. The regulated DC voltage may also be used to provide direct power to one or more electronic components of the vehicle 402. In certain aspects, the transmit circuitry 404 and the receive circuitry 418 may be configured to communicate via a communication channel 420 (e.g., Bluetooth, Zigbee, cellular, etc.), which is separate from the wireless transfer between coils 410 and 412.

### Example Adaptive ADC Control for Living Object Protection

Concerns over the safety of using wireless charging are being addressed by foreign object detection (FOD) and living object protection (LOP) systems. These concerns arise from scenarios where a small child or an animal, such as a dog, is under an electric vehicle (EV) during charging. Excessive heating of stray objects which are energized by the inductive power transfer between the base and vehicle pads runs the risk of causing skin burns or fire. FOD and LOP systems are being designed to conform to regulations which make wireless electric vehicle charging (WEVC) safe and to be reliable including minimizing false alarms and missed detections.

One example apparatus for living object protection in a wireless power transfer application may detect objects in a detection area of a wireless power transfer system. The apparatus generally includes a plurality of radar transceivers and at least one processor configured to receive radar data from the plurality of radar transceivers, detect an object in the detection area based on the received radar data, and potentially adjust the detection area. The apparatus may be configured to adjust the detection area based on at least one of a type of chargeable vehicle present, an amount of power being wirelessly transferred by the wireless power transfer system, an alignment of a vehicle with the wireless power transfer system, or a speed of the object approaching the detection area.

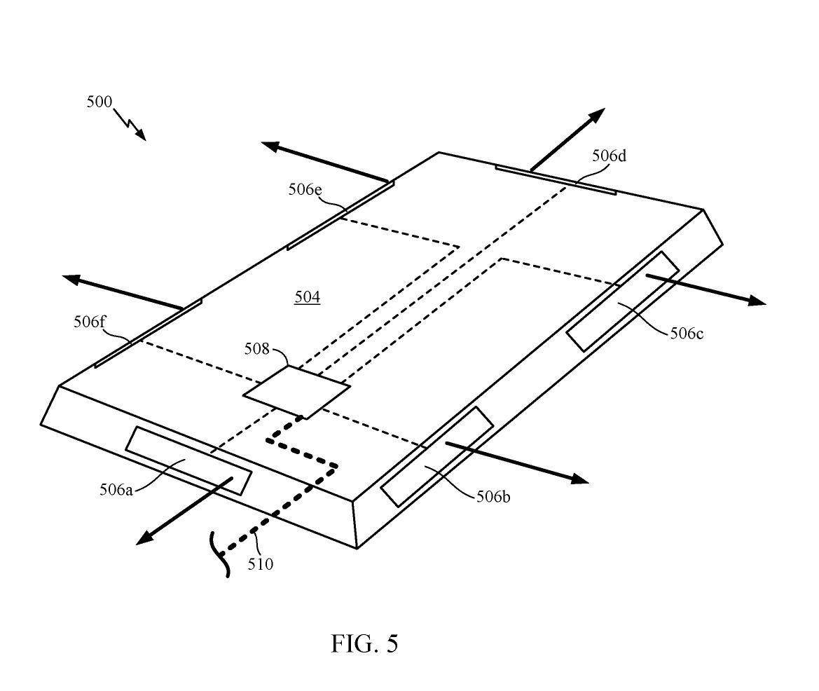

Certain aspects of the present disclosure are directed to automatically detecting living and/or moving objects that may be located in a detection area around an inductive power transfer (IPT) base pad. FIG. 5 illustrates an example living or moving object detection system 500 integrated into a base pad 504 of a wireless power transmitter, in accordance with certain aspects of the present disclosure and as presented in U.S. Publication No. 2016/0109564 to Sieber et al., filed Jul. 16, 2015 and entitled “Systems, Methods, and Apparatus for Living Object Protection in Wireless Power Transfer Applications,” which is assigned to the assignee of the present application and is incorporated by reference in its entirety. As shown in FIG. 5, the base pad 504 may include a plurality of radar modules 506a, 506b, 506c, 506d, 506e, and 506f (collectively “radar modules 506”), each integrated into or mounted onto a side (e.g., a lateral surface) of the base pad 504. In some implementations, each radar module may be configured to operate independently of the other radar modules 506 such that signals generated by the other radar modules do not interfere with the operation of a particular radar module.

Because the radar modules 506 are mounted on the sides of the base pad 504, LOP coverage on all sides or along an entire perimeter of the base pad 504 may be provided. Mounting the radar modules 506 to the side of the base pad 504 may enable each module to have a substantially horizontal field of view (e.g., the transceiver on each of the modules 506a-506f may be directed substantially away from the base pad 504 and may be configured to transmit and receive in directions substantially parallel to a plane of a surface on which the base pad 504 is located, as shown by the heavy arrows in FIG. 5). In such implementations, the printed circuit boards (PCBs) of each of the radar modules 506a-506f may be integrated substantially vertically (e.g., substantially perpendicular to the plane of the surface on which the base pad 504 is located) or at a slightly tilted angle from vertical. This may allow for radar module integration without enlarging the dimensions of the base pad 504. In some other implementations, the radar modules 506 may be integrated just below a top surface of the base pad 504 such that the base pad 504 may be flush-mounted into a surface. In some other implementations, the radar modules 506 may be installed on a vehicle as either a vehicle-pad-integrated system or a discrete system.

As shown in FIG. 5, the base pad 504 may additionally include a processing system 508 (e.g., including one or more processors) connected to each of the radar modules 506a-506f, as depicted by the thin dashed lines. The processing system 508 may be configured to receive radar data from the plurality of radar transceivers on the radar modules 506. The processing system 508 may utilize raw radar data from one or more of the radar modules 506, in isolation (e.g., considering raw radar data from only one radar module) or in combination (e.g., considering raw radar data from multiple radar modules in some aggregate fashion), to determine a presence of a moving or living object within an adjustable detection region, area, or zone. Accordingly, the processing system 508 and the plurality of radar modules 506 may provide a “virtual electronic fence” around the base pad 504 for detecting any living or moving object in the detection region. In addition, the processing system 508 may be configured to provide raw or processed radar data to another portion of the WEVC system and receive status information or other data from the WEVC system. For such purposes, the processing system 508 may be in communication with other portions of the WEVC system via a communication link 510 (depicted by the heavy dotted line), at least to communicate an object detection trigger to the WEVC system for shutting down charging or for reducing an amount of power that is wirelessly transmitted by the base pad 504. This or another communication link may also be utilized to receive the status information or other data from the WEVC system at least for dynamically adjusting a detection area of the detection system.

In an LOP system, each of the radar modules 506a-506f may include an analog-to-digital converter (ADC) to sample the received signal and convert the sampled signal to a digital signal for further processing in the digital domain. The LOP system is designed to operate in a relatively wide temperature range. However, when the temperature changes, the mean (bias) and the dynamic range of the received signal may most likely also change due to the analog circuits in the front-end of each radar module. This may lead to several issues in a conventional LOP system. For example, the received signal may not be correctly sampled by the ADC, which may be due primarily to offset error. That is, the mean (bias) change of the received signal may cause part of the sampled signal to fall outside of the ADC's dynamic range. This may result in nonlinear behavior of the ADC, such as clipping, compression, etc. Furthermore, different radar modules 506 have slightly different analog behavior, which results in different threshold settings. One method to overcome these issues involves measuring the temperature of each radar module and adjusting the associated ADC accordingly. This method may entail calibrating the ADC prior to operation over various temperatures and storing the results in a look-up table (LUT) for future reference during normal operation. Another method entails estimating the received signal level first during operation. When the change in the estimated signal is larger than a preset threshold, then the ADC is adjusted accordingly. However, this alternative method involves a second-order estimation, which may be overly complex.

Aspects of the present disclosure provide techniques and apparatus for adaptively controlling the ADC in each radar module, with neither a temperature measurement nor an estimation of changes in the received signal. Certain aspects of the present disclosure estimate the received signal level and compare the received signal with a preset target signal level. The received signal level estimation may be performed continuously, which may refer to once per sample period of the ADC. For other aspects, the receive signal level estimation may be performed one time during an interval spanning multiple sample periods of the ADC. For certain aspects, the preset target signal level is calculated based on one or more radar parameters. Based on the comparison, one or more ADC settings may be adaptively adjusted to make the received signal level converge to the preset target signal level.

Adaptive controlling of the ADC settings to best fit the received signal in each radar module ensures each ADC is operating at its optimal, or at least designated, working point. This also enables the LOP system to work properly and reliably at all temperatures in the system temperature range. Moreover, aspects of the present disclosure involve no calibration for temperature compensation and simplify the complexity of the detection threshold calibration, due to all radar modules operating at similar working points. The increased accuracy over the temperature range may also increase the LOP system detection sensitivity.

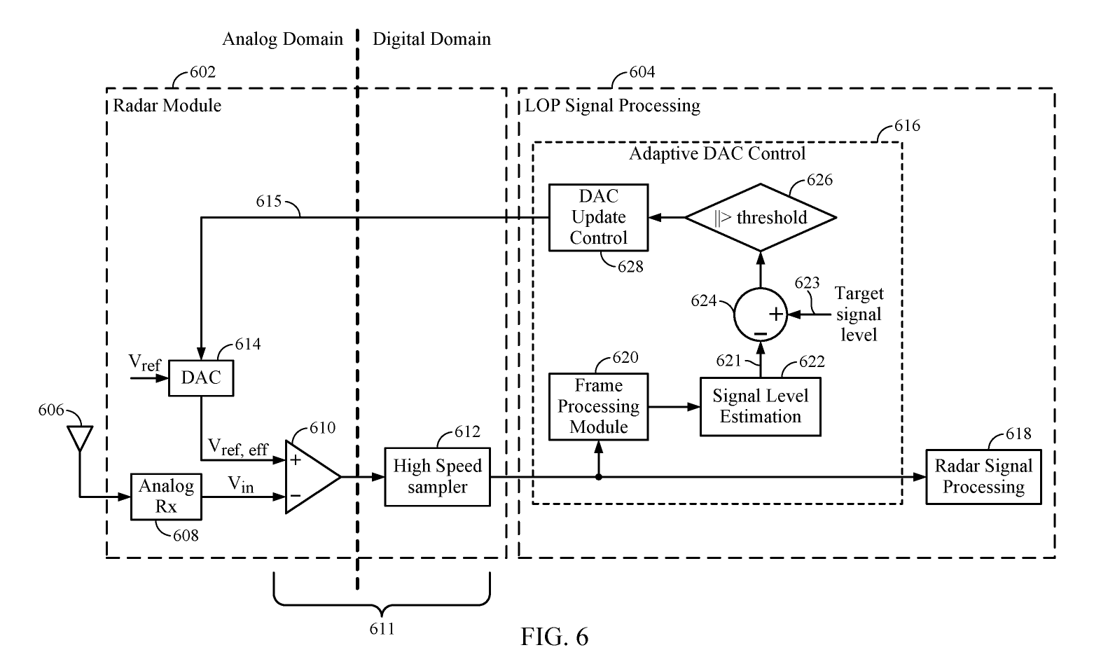

FIG. 6 is a block diagram of a radar module front-end 602 and a back-end 604 for adaptive control of an analog-to-digital converter (ADC) in the front-end, in accordance with certain aspects of the present disclosure. The radar module front-end 602 may represent the front-end in each of the radar modules 506a-506f, while the back-end 604 (or at least a portion thereof) may be implemented in the processing system 508 of FIG. 5. The radar module front-end 602 may include an antenna 606, analog receive (Rx) circuitry 608, an ADC 611 including an analog voltage comparator 610 and a high speed sampler 612, and a digital-to-analog converter (DAC) 614. The back-end 604 may include an adaptive DAC control module 616 and a radar signal processing module 618. Each of the radar modules 506a-506f of FIG. 5 may have an adaptive DAC control module 616 associated therewith.

Signals received by the antenna 606 of the radar module front-end 602 may be processed (e.g., tuned, amplified, buffered, filtered, downconverted to baseband, etc.) in the analog domain by the analog Rx circuitry 608. The output of the analog Rx circuitry 608 (labeled “Vᵢₙ”) and an effective reference voltage for the ADC (labeled “V_{ref,eff}”) may be compared by the comparator 610, and the output of the comparator 610 may be sampled by the high speed sampler 612. The high speed sampler 612 is configured to discretely sample an input signal (e.g., the output of the comparator 610) at a specified sampling frequency (i.e., the clock frequency for the sampler), which may be on the order of several GHz (e.g., around 38 GHz). For example, the sampler 612 may be implemented with an electronic switch (e.g., a transmission gate) controlled by a clock signal with the sampling frequency and coupled to a capacitive element (e.g., acting as a holding capacitor). For certain aspects, the capacitive element may be implemented by one or more logic gates (e.g., two inverters connected in series). The DAC 614 may receive a control signal 615 from the back-end 604 and a reference voltage (labeled “V_{ref}”) and may generate the effective reference voltage (V_{ref, eff}) for the ADC based thereon.

The adaptive DAC control module 616 may receive the digital, sampled signal from the ADC 611 and perform digital signal processing thereon to generate the control signal 615 for the DAC 614 to effectively adaptively control the ADC 611. For certain aspects, as illustrated in FIG. 6, the adaptive DAC control module 616 may include a frame processing module 620, a signal level estimation module 622, a difference module 624, a decision module 626, and a DAC update control module 628. The frame processing module 620 may process a frame, where a frame generally refers to a window (e.g., a period) of digital, sampled signals in the time domain. In this case, the sampled signals are received from the ADC 611. For certain aspects, the frame processing module 620 may determine the mean of each frame. For other aspects, the frame processing module 620 may use other statistically significant values for a data set, such as the median. For certain aspects, the frame processing module 620 may operate with a sliding window that moves with each new digital sample from the ADC 611.

The output of the frame processing module 620 is sent to the signal level estimation module 622 for estimation of the signal level. The estimation module 622 may estimate the signal level using any of various suitable estimation algorithms. For certain aspects, the signal level estimation module 622 may estimate the signal level based on multiple frame means from different frames. For some aspects, the signal level estimation module 622 may use a moving average of the frame means to estimate the signal level. Alternatively, the signal level estimation module 622 may estimate the signal level using a mean squared error (MSE) or a minimum mean square error (MMSE) of the sampled signal level.

The difference module 624 determines the difference between the estimated signal level (as output by the signal level estimation module 622 and referred to as the actual signal level 621) and a target signal level 623. For certain aspects, the target signal level 623 is calculated based on one or more characteristics of the radar modules, such as number of iterations, pulses per step, maximum DAC sweep value, minimum DAC sweep value, and/or DAC sweep step size. For certain aspects, the maximal value after ADC quantization may be determined, and the target signal level 623 may be calculated as half of the maximal value after ADC quantization.

The decision module 626 determines whether the absolute value (H) of the difference output by the difference module 624 is greater than a threshold. If so, the decision module 626 may output a signal to the DAC update control module 628 to output the control signal 615 for adjusting the DAC 614. If the absolute value of the difference from the difference module 624 is not greater than the threshold, the decision module 626 may do nothing for certain aspects, or may output a different signal to the DAC update control module 628. In this manner, the effective reference voltage (V_{ref, eff}) for the ADC 611 may be adjusted to tweak the settings for the ADC to make the received signal level converge to the preset target signal level.

The radar signal processing module 618 may be configured to receive the digital, sampled signal (e.g., radar data) from the ADC 611 and perform digital signal processing thereon to determine the presence of an object in a detection area associated with a particular one of the radar modules 506. For certain aspects, the radar signal processing module 618 may function and perform operations similar to the processing system 508 of FIG. 5.

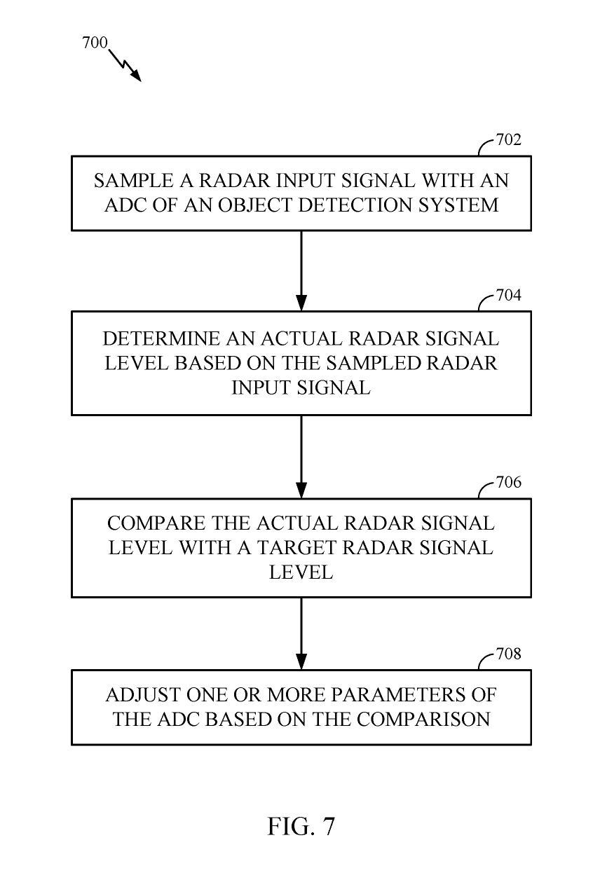

FIG. 7 is a flow diagram of example operations 700 for an object detection system with adaptive control of an ADC, in accordance with certain aspects of the present disclosure. The operations 700 may be performed by an apparatus for objection detection in a wireless power transfer application, such as a base pad 504 with one or more radar modules 506 for implementing LOP, as illustrated in FIG. 5.

The operations 700 may begin, at block 702, with the apparatus sampling a radar input signal (e.g., Vᵢₙ) with the ADC (e.g., ADC 611). At block 704, the apparatus may determine an actual radar signal level (e.g., actual signal level 621) based on the sampled radar input signal. At block 706, the apparatus may compare the actual radar signal level with a target radar signal level (e.g., target signal level 623). At block 708, the apparatus may adjust one or more parameters of the ADC based on the comparison at block 706.

According to certain aspects, the operations 700 may further involve the apparatus calculating the target radar signal level before the comparison at block 706. The calculation may be based on one or more properties of the apparatus.

According to certain aspects, the comparing at block 706 entails determining a difference between the target radar signal level and the actual radar signal level and comparing the difference with a threshold.

According to certain aspects, the one or more parameters include a reference voltage (e.g., V_{ref,eff}) for the ADC. In this case, the adjusting at block 708 may involve controlling a digital-to-analog converter (DAC) (e.g., DAC 614) configured to generate the reference voltage for the ADC. For certain aspects, the DAC receives a control signal (e.g., control signal 615) based on the comparison (e.g., at block 706) and another reference voltage (e.g., V_{ref}), and in this case, the reference voltage for the ADC is based on the control signal and the other reference voltage.

According to certain aspects, the adjusting at block 708 involves generating at least one control signal (e.g., control signal 615) configured to adjust the one or more parameters of the ADC based on the comparison.

According to certain aspects, the determining at block 704 entails determining a mean of the sampled radar input signal over a period (e.g., a window).

According to certain aspects, the determining at block 704 includes continuously determining the actual radar signal level. For certain aspects, continuous determination may include once per sample period of the ADC. For other aspects, the determining at block 704 entails determining the actual radar signal level once per several sample periods of the ADC.

According to certain aspects, the operations 700 further involve the apparatus receiving the radar input signal via one of a plurality of radar modules (e.g., radar modules 506) of the object detection system. In this case, the operations 700 may also include the apparatus calculating the target radar signal level before the comparison at block 706 based on one or more characteristics of the plurality of radar modules. For certain aspects, the operations 700 further include the apparatus performing radar signal processing on the sampled radar input signal.

According to certain aspects, the operations 700 further entail the apparatus receiving the radar input signal via one of a plurality of radar modules (e.g., radar modules 506) of the object detection system. In this case, the operations 700 may also include the apparatus detecting a presence of an object (e.g., a living object, such as an animal) in a detection area of at least one of the radar modules, based on the sampled radar input signal.

The various operations or methods described above may be performed by any suitable means capable of performing the corresponding functions. The means may include various hardware and/or software component(s) and/or module(s), including, but not limited to a circuit, an application-specific integrated circuit (ASIC), or processor. Generally, where there are operations illustrated in figures, those operations may have corresponding counterpart means-plus-function components with similar numbering.

For example, means for wirelessly transmitting power may include a transmitter (e.g., transmitter 104 in FIG. 1 or transmitter 204 in FIG. 2), which may also be referred to as a power transmitting unit (PTU). Means for sampling may include an ADC, such as the ADC 611 illustrated in FIG. 6. Means for determining an actual radar signal level may include a processing system, such as the adaptive DAC control module 616 depicted in FIG. 6, and more specifically, may include the frame processing module 620 and/or the signal level estimation module 622 of FIG. 6. Means for comparing may include a processing system, such as the adaptive DAC control module 616 shown in FIG. 6, and more specifically may include the difference module 624 and/or the decision module 626. Means for adjusting may include a processing system, such as the adaptive DAC control module 616 (and more specifically the control module 628) and/or a DAC 614 illustrated in FIG. 6. Means for calculating may include a processing system, such as the adaptive DAC control module 616 depicted in FIG. 6. Means for generating a reference voltage may include a DAC, such as the DAC 614 portrayed in FIG. 6. Means for receiving an RF signal may include an antenna, such as the antenna 606 illustrated in FIG. 6. Means for processing the RF signal may include signal processing circuitry (e.g., an amplifier, filter, downconverter, etc.), such as the analog Rx circuitry 608 represented in FIG. 6. Means for detecting a presence of an object may include a processing system, such as the processing system 508 depicted in FIG. 5 or the radar signal processing module 618 illustrated in FIG. 6.

As used herein, the term “determining” encompasses a wide variety of actions. For example, “determining” may include calculating, computing, processing, deriving, investigating, looking up (e.g., looking up in a table, a database, or another data structure), ascertaining, and the like. Also, “determining” may include receiving (e.g., receiving information), accessing (e.g., accessing data in a memory), and the like. Also, “determining” may include resolving, selecting, choosing, establishing, and the like.

As used herein, a phrase referring to “at least one of” a list of items refers to any combination of those items, including single members. As an example, “at least one of: a, b, or c” is intended to cover: a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c).

The various illustrative logical blocks, modules, and circuits described in connection with the present disclosure may be implemented or performed with a general purpose processor, a digital signal processor (DSP), an ASIC, a field programmable gate array (FPGA) or other programmable logic device (PLD), discrete gate or transistor logic, discrete hardware components, or any combination thereof designed to perform the functions described herein. A general-purpose processor may be a microprocessor, but in the alternative, the processor may be any commercially available processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

The methods disclosed herein comprise one or more steps or actions for achieving the described method. The method steps and/or actions may be interchanged with one another without departing from the scope of the claims. In other words, unless a specific order of steps or actions is specified, the order and/or use of specific steps and/or actions may be modified without departing from the scope of the claims.

The functions described may be implemented in hardware, software, firmware, or any combination thereof. If implemented in hardware, an example hardware configuration may comprise a processing system in a wireless node. The processing system may be implemented with a bus architecture. The bus may include any number of interconnecting buses and bridges depending on the specific application of the processing system and the overall design constraints. The bus may link together various circuits including a processor, machine-readable media, and a bus interface. The bus interface may be used to connect a network adapter, among other things, to the processing system via the bus. The network adapter may be used to implement the signal processing functions of the physical (PHY) layer. In the case of a user terminal, a user interface (e.g., keypad, display, mouse, joystick, etc.) may also be connected to the bus. The bus may also link various other circuits such as timing sources, peripherals, voltage regulators, power management circuits, and the like, which are well known in the art, and therefore, will not be described any further.

The processing system may be configured as a general-purpose processing system with one or more microprocessors providing the processor functionality and external memory providing at least a portion of the machine-readable media, all linked together with other supporting circuitry through an external bus architecture. Alternatively, the processing system may be implemented with an ASIC with the processor, the bus interface, the user interface in the case of an access terminal), supporting circuitry, and at least a portion of the machine-readable media integrated into a single chip, or with one or more FPGAs, PLDs, controllers, state machines, gated logic, discrete hardware components, or any other suitable circuitry, or any combination of circuits that can perform the various functionality described throughout this disclosure. Those skilled in the art will recognize how best to implement the described functionality for the processing system depending on the particular application and the overall design constraints imposed on the overall system.

It is to be understood that the claims are not limited to the precise configuration and components illustrated above. Various modifications, changes and variations may be made in the arrangement, operation and details of the methods and apparatus described above without departing from the scope of the claims.

What is claimed is:

1. A method for operating an object detection system, comprising:
sampling a radar input signal with an analog-to-digital converter (ADC) of the object detection system;
determining an actual radar signal level based on the sampled radar input signal;
comparing the actual radar signal level with a target radar signal level; and
adjusting one or more parameters of the ADC based on the comparison.

2. The method of claim 1, further comprising:
receiving the radar input signal via one of a plurality of radar modules of the object detection system; and
detecting a presence of an object in a detection area of at least one of the radar modules, based on the sampled radar input signal.

3. The method of claim 1, wherein the comparing comprises:
determining a difference between the target radar signal level and the actual radar signal level; and
comparing the difference with a threshold.

4. The method of claim 1, wherein the one or more parameters comprise a reference voltage for the ADC.

5. The method of claim 4, wherein the adjusting comprises controlling a digital-to-analog converter (DAC) configured to generate the reference voltage for the ADC.

6. The method of claim 5, wherein the DAC receives a control signal based on the comparison and another reference voltage and wherein the reference voltage for the ADC is based on the control signal and the other reference voltage.

7. The method of claim 1, wherein the adjusting comprises generating at least one control signal configured to adjust the one or more parameters of the ADC based on the comparison.

8. The method of claim 1, wherein the determining comprises determining a mean of the sampled radar input signal over a period.

9. The method of claim 1, wherein the determining comprises continuously determining the actual radar signal level, once per sample period of the ADC.

10. The method of claim 1, further comprising:
receiving the radar input signal via one of a plurality of radar modules of the object detection system; and
calculating the target radar signal level before the comparison based on one or more characteristics of the plurality of radar modules.

11. The method of claim 1, further comprising calculating the target radar signal level before the comparison.

12. An apparatus for object detection in a wireless power transfer application, comprising:
an analog-to-digital converter (ADC) configured to sample a radar input signal; and
a processor having an input coupled to an output of the ADC and configured to:
determine an actual radar signal level based on the sampled radar input signal;
compare the actual radar signal level with a target radar signal level; and
output at least one control signal configured to adjust one or more parameters of the ADC based on the comparison.

13. The apparatus of claim 12, further comprising a plurality of radar modules, at least one of the radar modules being configured to receive a radio frequency (RF) signal and to process the RF signal to generate the radar input signal, wherein the processor is further configured to detect a presence of an object in a detection area of the at least one of the radar modules, based on the sampled radar input signal.

14. The apparatus of claim 12, wherein the processor is configured to compare the actual radar signal level with the target radar signal level by:
determining a difference between the target radar signal level and the actual radar signal level; and
comparing the difference with a threshold.

15. The apparatus of claim 12, wherein the one or more parameters comprise a reference voltage for the ADC.

16. The apparatus of claim 15, further comprising a digital-to-analog converter (DAC) configured to generate the reference voltage for the ADC.

17. The apparatus of claim 16, wherein the ADC comprises:
a comparator having a first input coupled to a node with the radar input signal and a second input coupled to an output of the DAC; and
a sampler having an input coupled to an output of the comparator.

18. The apparatus of claim 16, wherein:
the DAC has an input coupled to an output of the processor;
the DAC is configured to receive the control signal and another reference voltage; and
the reference voltage for the ADC is based on the control signal and the other reference voltage.

19. The apparatus of claim 12, wherein the processor is configured to determine the actual radar signal level by determining a mean of the sampled radar input signal over a period.

20. The apparatus of claim 12, wherein the processor is configured to determine the actual radar signal level by determining the actual radar signal level once per several sample periods of the ADC.

21. The apparatus of claim 12, further comprising a plurality of radar modules, at least one of the radar modules being configured to receive a radio frequency (RF) signal and process the RF signal to generate the radar input signal, wherein the processor is further configured to calculate the target radar signal level before the comparison based on one or more characteristics of the plurality of radar modules.

22. The apparatus of claim 12, wherein the processor is further configured to calculate the target radar signal level before the comparison.

23. An apparatus for object detection in a wireless power transfer application, comprising:
means for sampling a radar input signal;
means for determining an actual radar signal level based on the sampled radar input signal;
means for comparing the actual radar signal level with a target radar signal level; and
means for adjusting one or more parameters of the means for sampling based on the comparison between the actual radar signal level and the target radar signal level.

24. The apparatus of claim 23, wherein the means for comparing is configured to:
determine a difference between the target radar signal level and the actual radar signal level; and
compare the difference with a threshold.

25. The apparatus of claim 23, wherein the one or more parameters comprise a reference voltage for the means for sampling.

26. The apparatus of claim 25, further comprising means for generating the reference voltage for the means for sampling, wherein the means for adjusting is configured to control the means for generating.

27. The apparatus of claim 26, wherein the means for generating is configured to receive a control signal based on the comparison and another reference voltage and wherein the reference voltage for the means for sampling is based on the control signal and the other reference voltage.

28. The apparatus of claim 23, wherein the means for determining is configured to determine a mean of the sampled radar input signal over a period.

29. The apparatus of claim 23, further comprising:
means for receiving a radio frequency (RF) signal;
means for processing the RF signal to generate the radar input signal; and
means for detecting a presence of an object in a detection area of the means for receiving, based on the sampled radar input signal.

30. The apparatus of claim 23, further comprising:
means for receiving a radio frequency (RF) signal;
means for processing the RF signal to generate the radar input signal; and
means for calculating the target radar signal level for the means for comparing, based on one or more characteristics of at least one of the means for receiving or the means for processing.
